(19) United States
(12) Patent Application Publication
(10) Pub. No.: US 2009/0004797 A1
(43) Pub. Date: Jan. 1, 2009

(54) METHOD FOR FABRICATING SEMICONDUCTOR DEVICE

(75) Inventor: Min-Suk LEE, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 11/965,706

(22) Filed: Dec. 27, 2007

(30) Foreign Application Priority Data
Jun. 26, 2007 (KR) 10-2007-0062813

(51) Int. Cl. H01L 21/336

(52) U.S. Cl. 438/270; 257/E21.41

(57) ABSTRACT

A method of fabricating a semiconductor device includes forming a plurality of pillars which are arranged on a substrate in a first direction and a second direction that intersects the first direction, thereby forming a resulting structure, forming a capping layer on the resulting structure including the pillars, removing the capping layer formed on the substrate between the pillars to expose the substrate between the pillars, thereby forming a resulting structure, forming a metal layer on the resulting structure, forming a silicide layer on the exposed substrate between the pillars by applying a first heat treatment to the metal layer, removing a non-reacted silicide layer, and forming an isolation trench in the substrate which is between rows of the pillars arranged in the first direction and is under the silicide layer to define bit lines which surround the pillars and are extended to the first direction.

### CROSS-REFERENCE TO RELATED APPLICATIONS

The present invention claims priority of Korean patent application number 10-2007-0062813, filed on Jun. 26, 2007, which is incorporated by reference in its entirety.

### BACKGROUND OF THE INVENTION

The present invention relates to a semiconductor device fabrication technology and, more particularly, to a method of fabricating a semiconductor device with a vertical channel transistor.

As a semiconductor device becomes highly integrated, the channel length of a transistor is gradually reduced. However, the reduction in the channel length of the transistor causes a short channel effect such as a DIBL (Drain Induced Barrier Lowering) phenomenon, a hot carrier effect and a punch through effect. In order to solve such a limitation, various methods, such as a method of reducing the depth of a junction and a method of forming a recess to increase the effective channel length, are suggested.

However, with an increase in the integration of the semiconductor device, the size of the transistor is required to be smaller, especially in a gigabit dynamic random access memory (DRAM). That is, the transistor of the gigabit DRAM is required to have a device area of less than 8 F² (F: minimum feature size), preferably, a device area of 4 F². Therefore, the conventional planar transistor, in which a gate electrode is formed on a semiconductor substrate and a junction is formed at each side of the gate electrode, has difficulty in satisfying the required device area even though the channel length of the transistor is scaled down. One solution is the use of a vertical channel transistor.

FIG. 1 illustrates a perspective view of a conventional semiconductor device with a vertical channel transistor.

Referring to FIG. 1, a plurality of pillars P is formed on a substrate 100. The pillars P are made of the same material as the substrate 100 and are arranged in a first direction of X-X′ and a second direction of Y-Y′ which are perpendicular to each other. The pillars P are formed by etching the substrate 100 using a hard mask pattern (not illustrated).

A buried bit line 101, which surrounds the pillars P and extends along the first direction of X-X′, is formed on the substrate 100 among the pillars P arranged in the first direction of X-X′. The buried bit line 101 is formed through an impurity implantation in the substrate 100 and is separated by an isolation trench T.

At the circumference of the pillar P, a gate electrode (not illustrated) which surrounds the pillar P is formed. A word line 102, which is electrically connected to the gate electrode and extended to the second direction of Y-Y′, is formed.

A storage electrode 104 is formed on the pillar P. A contact plug 103 can be interposed between the pillar P and the storage electrode 104.

Since a channel is formed in a direction vertical to a substrate surface in the semiconductor device described above, the channel length of the transistor can be increased regardless of a device area. Thus, the short channel effect can be prevented. Further, since the gate electrode surrounds the pillar, the channel width of a transistor is increased so that the operating current of the transistor can be improved.

However, a limitation occurs during the process of forming the buried bit line which degrades a device characteristic. The problem will be described in detail below referring to FIGS. 2A and 2B.

FIGS. 2A and 2B illustrate cross-sectional views of a method of fabricating a conventional semiconductor device with a vertical channel transistor. Particularly, FIGS. 2A and 2B are cross-sectional views taken along the broken line Y-Y′ of FIG. 1. Also, since the FIGS. 2A and 2B are provided for illustrating the problem occurring during the process of forming the buried bit line, a brief description will be provided.

As shown in FIG. 2A, a structure is suggested, which includes a substrate 200 having a plurality of pillars P arranged in a first direction and a second direction, hard mask patterns 201 formed on the pillars P, and a gate electrode 202 surrounding a lower portion of the pillar P. Then, bit line impurities are doped in the substrate 200 between the pillars P to form a bit line impurity region 203. At this time, the doping of the bit line impurities can be performed through an ion implantation.

As shown in FIG. 2B, an insulation layer 204 is formed on an entire substrate structure and then planarized.

A photoresist pattern (not illustrated) is formed on the planarized insulation layer 204. The insulation layer 204 is etched using the photoresist pattern as an etching mask so that the substrate 200 is partially exposed. The exposed substrate 200 is etched to a given depth. As a result, an isolation trench T, which extends along a direction parallel to the first direction, is formed in the substrate 200 between rows of the pillars P arranged in the first direction. At this time, the isolation trench T is formed to have a depth that extends below the bit line impurity region 203. Thus, a buried bit line 203A is defined, which surrounds the pillar P and extends along the first direction.

Subsequently, although not illustrated in the drawings, a process of forming a word line which is electrically connected to the gate electrode and extends along the second direction, a process of removing the hard mask pattern 201 to expose the pillar P and a process of forming a contact plug and a storage electrode on the exposed pillar P are sequentially performed.

However, since the buried bit line 203A is formed through the impurity implantation, the resistance Rs of the buried bit line 203A increases when compared with a conventional bit line using a metal layer. Particularly, as the area of the device is reduced, the resistance of the bit line formed by the impurity doping increases. FIG. 3 illustrates the resistance of the bit line according to the area of the device. Also, at the interface of the bit line formed through the impurity doping, a depletion region exists so that the capacitance of the bit line increases.

### SUMMARY OF THE INVENTION

The present invention is directed to providing a method of fabricating a semiconductor device having a vertical channel transistor, where a bit line is formed by using a silicide formation process instead of a conventional impurity doping process.

According to an aspect of the present invention, there is provided a method of fabricating a semiconductor device, the method includes forming a plurality of pillars which are arranged on a substrate in a first direction and a second direction that intersects the first direction, thereby forming a resulting structure, forming a capping layer on the resulting structure including the pillars, removing the capping layer formed on the substrate between the pillars to expose the substrate between the pillars, thereby forming a resulting structure, forming a metal layer on the resulting structure, forming a silicide layer on the exposed substrate between the pillars by applying a first heat treatment to the metal layer, removing a non-reacted silicide layer, and forming an isolation trench in the substrate which is between rows of the pillars arranged in the first direction and is under the silicide layer to define bit lines which surround the pillars and extend along the first direction.

According to an aspect of the present invention, there is provided a method of fabricating a semiconductor device. The method includes forming first and second pillars on a silicon substrate, the first and second pillars being of the same material as the substrate, the first and second pillars defining a space therebetween, forming a capping layer over the first and second pillars and the space defined therebetween, removing a portion of the capping layer formed over the space defined between the first and second pillars, wherein a portion of the substrate provided between the first and second pillars is exposed after the capping layer is removed, forming a metal layer over the capping layer and the exposed portion of the substrate that is provided between the first and second pillars, applying a first heat treatment to the metal layer, so that a first portion of the metal layer in contact with the exposed portion of the substrate is converted to a silicide layer and a second portion of the metal layer not in contact with the exposed portion of the substrate remains as the metal layer, removing the second portion of the metal layer, wherein the silicide layer remains at the space defined between the first and second pillars after the second portion of the metal layer is removed, and forming an isolation trench in the substrate at the space defined between the first and second pillars, the isolation trench extending below the silicide layer and separating the silicide layer into a first silicide structure and a second silicide structure, the first silicide structure being associated with the first pillar and the second silicide structure being associated with the second pillar.

According to another aspect of the present invention, there is provided a method of fabricating a semiconductor device. The method includes forming first and second pillars on a substrate, the first and second pillars defining a space therebetween, the first and second pillars defining first and second gate electrodes, forming a capping layer over the first and second pillars and the space defined therebetween, removing a portion of the capping layer formed over the space defined between the first and second pillars, wherein a portion of the substrate provided between the first and second pillars is exposed after the capping layer is removed, forming a metal layer over the capping layer and the exposed portion of the substrate that is provided between the first and second pillars, applying a first heat treatment to the metal layer, so that a first portion of the metal layer in contact with the exposed portion of the substrate is converted to a silicide layer, and forming an isolation trench in the substrate at the space defined between the first and second pillars, the isolation trench extending below the silicide layer and separating the silicide layer into a first silicide structure and a second silicide structure, the first silicide structure being associated with the first pillar and the second silicide structure being associated with the second pillar.

### BRIEF DESCRIPTION OF THE DRAWINGS

FIG. 1 illustrates a perspective view of a conventional semiconductor device with a vertical channel transistor.

FIGS. 2A and 2B illustrate cross-sectional views of a method of fabricating a conventional semiconductor device with a vertical channel transistor.

FIG. 3 illustrates a bit line resistance based on a device area.

FIGS. 4A to 4I illustrate cross-sectional views of a method of fabricating a semiconductor device with a vertical channel transistor according to one embodiment of the present invention.

### DETAILED DESCRIPTION OF THE SPECIFIC EMBODIMENTS

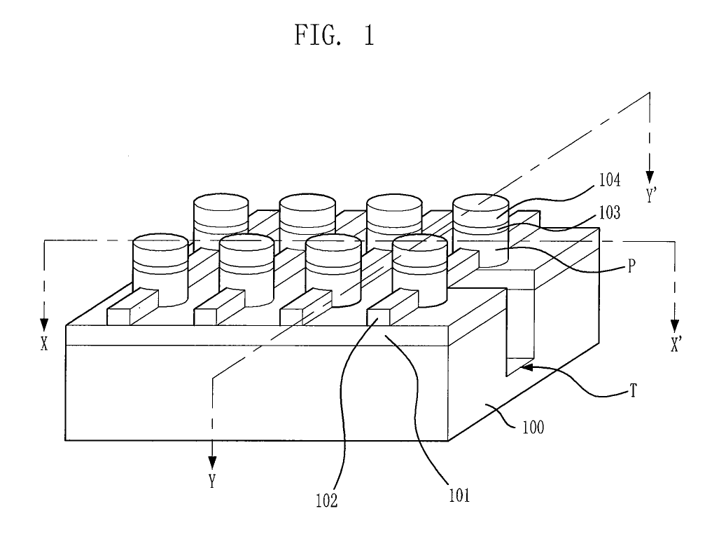

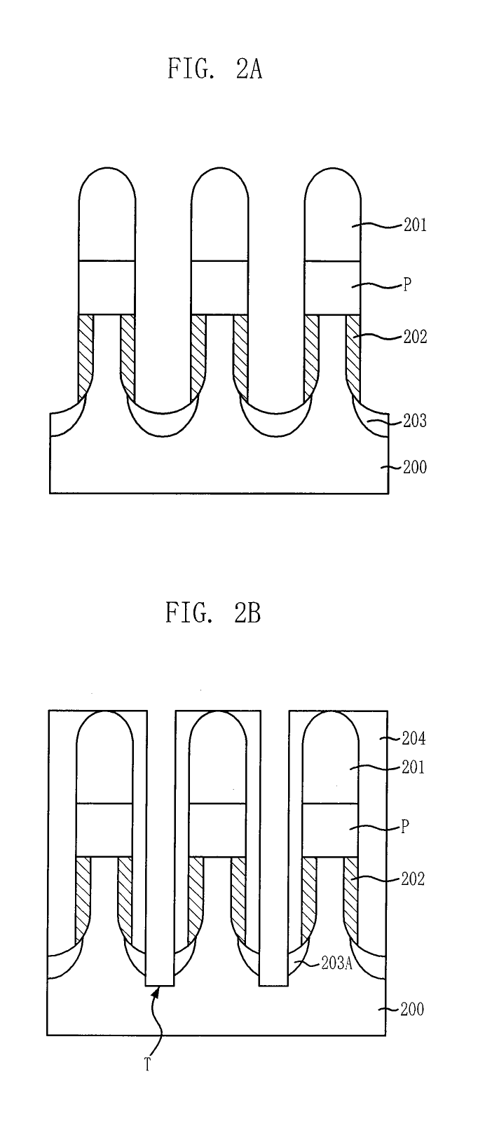

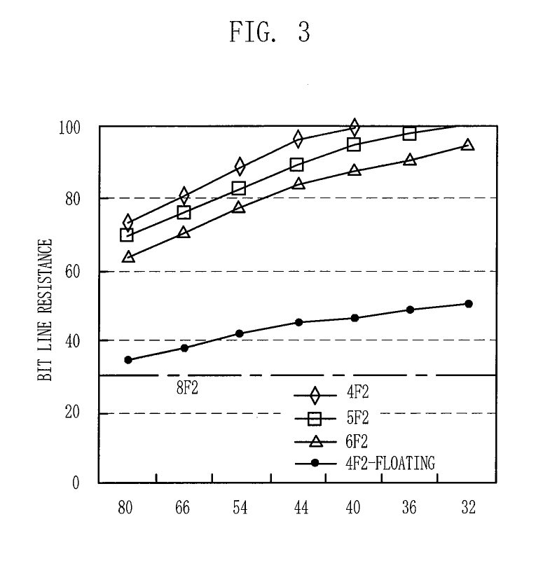

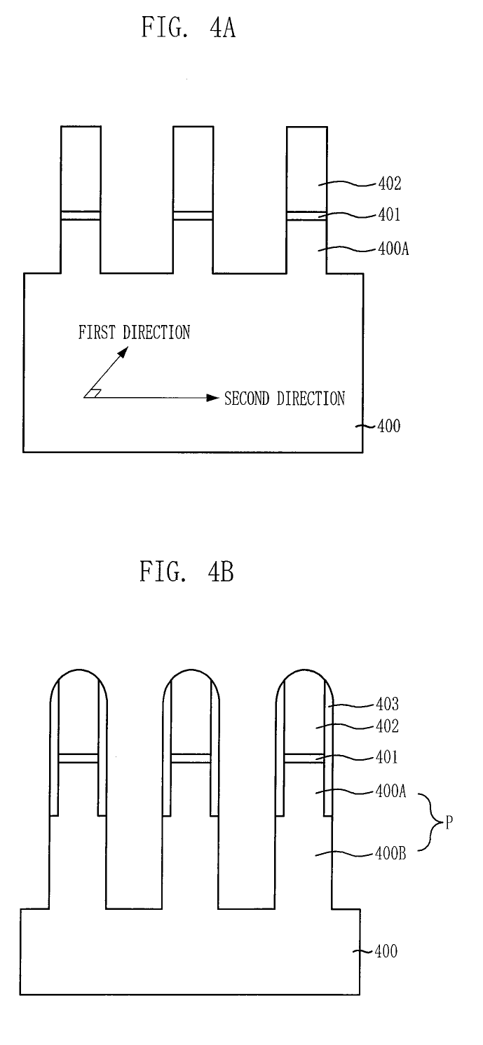

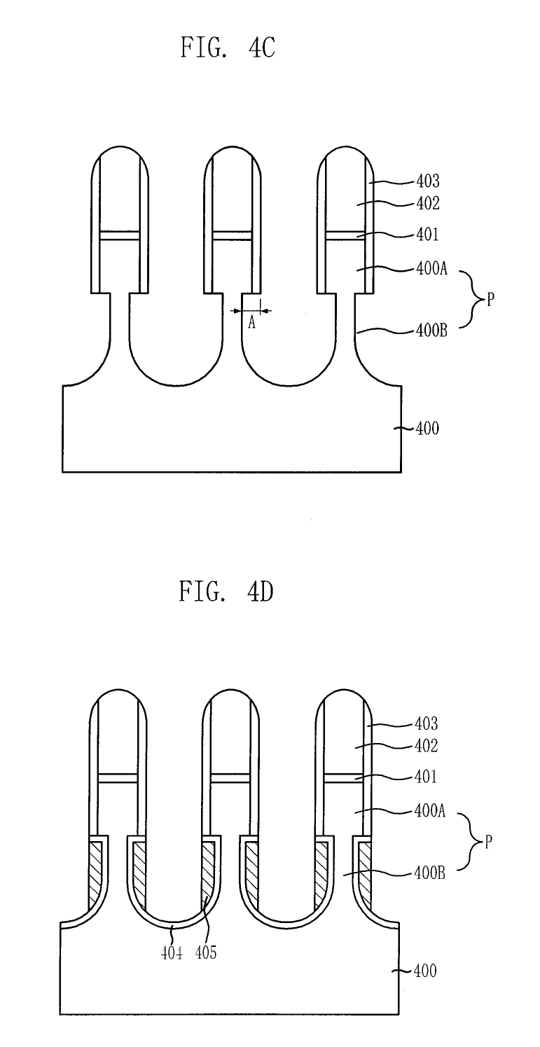

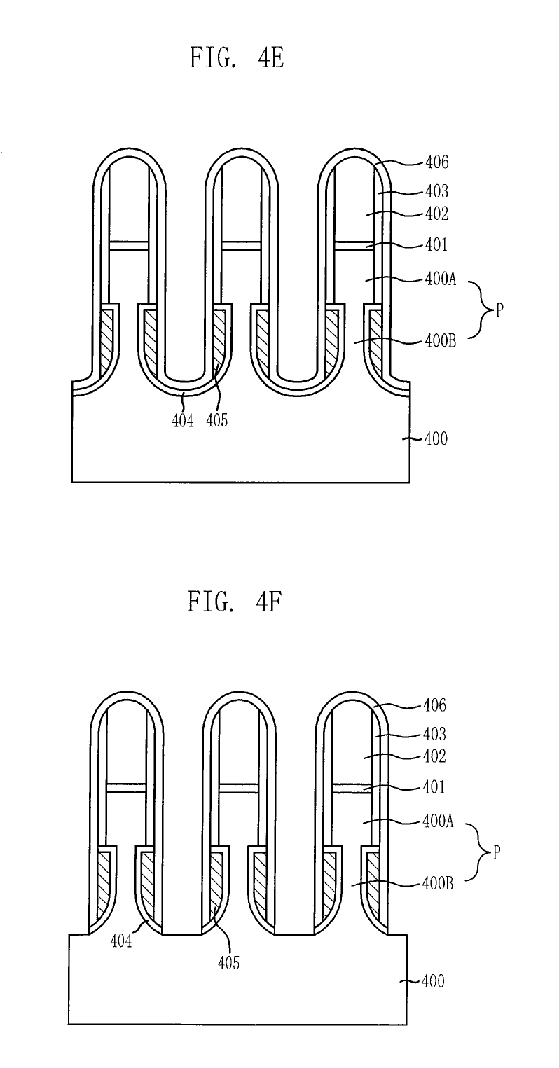

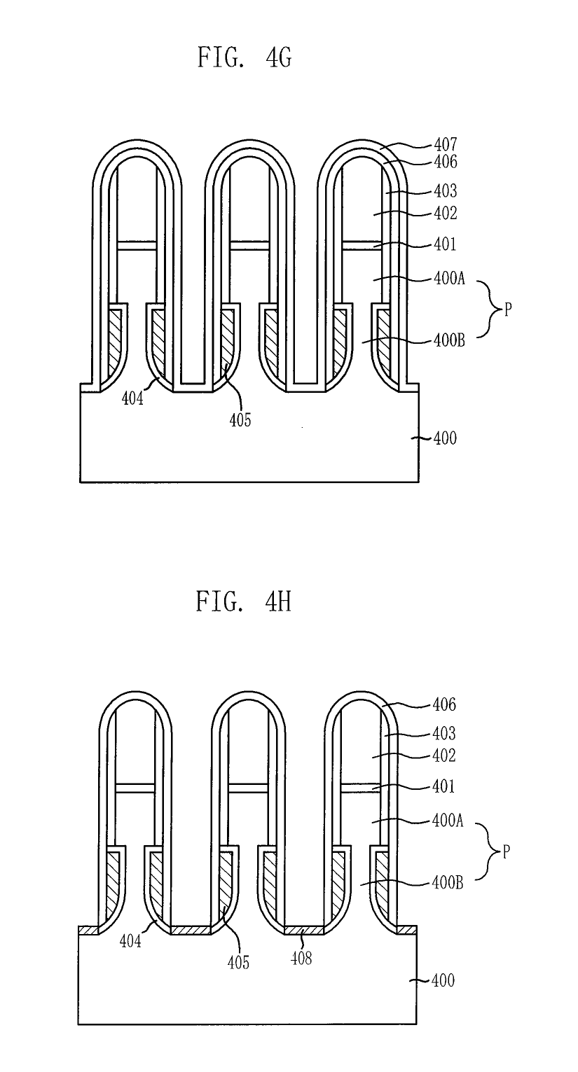

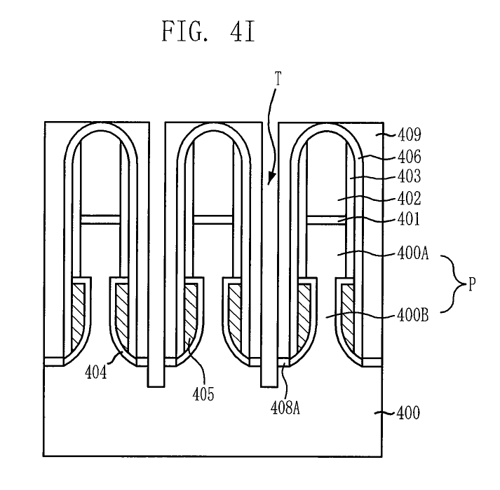

FIGS. 4A to 4I illustrate cross-sectional views of a method of fabricating a semiconductor device with a vertical channel transistor according to one embodiment of the present invention. Particularly, FIGS. 4A to 4I are cross-sectional views taken along the second direction of Y-Y′ in FIG. 1.

First, as shown in FIG. 4A, a plurality of hard mask patterns 402, which are arranged in a first direction and a second direction perpendicular to each other, are formed on a substrate 400. At this time, each of pad oxide layers 401 is provided below each hard mask pattern 402. Then, the substrate 400 is etched to a given depth using the hard mask patterns 402 as an etch mask to form a plurality of upper pillars 400A.

As shown in FIG. 4B, a spacer material layer is formed on a resulting structure and etched back to form spacers 403 on the sidewalls of the hard mask patterns 402 and the upper pillars 400A.

Then, the substrate 400 is etched to a given depth using the hard mask pattern 402 and the spacer 403 as an etching mask to form lower pillars 400B.

As a result of the process in FIG. 4B, the pillars P are formed as an active region including the upper and lower pillars 400A and 400B. The pluralities of the pillars P are arranged in the first direction and the second direction. Even though the hard mask patterns 402 have a planar square form, the pillar P becomes a cylindrical structure when the etching process is completed. There is a space between neighboring pillars, wherein the space defines a pillar from neighboring pillars.

As shown in FIG. 4C, a width A is isotropically etched from the sidewalls of the lower pillars 400B using the hard mask pattern 402 and the spacer 403 as an etching barrier (or etch stop). As a result, recesses are formed in the lower pillar 400B and in the substrate 400. At this time, the width A of the recesses at the lower pillars 400B corresponds to the thickness of a subsequent gate electrode.

As shown in FIG. 4D, a gate insulation layer 404 is formed on the surface of the exposed substrate 400. Then, after a conductive layer for a gate electrode is formed on a resulting structure, the conductive layer for the gate electrode is etched back to form the gate electrodes 405 which surround the recesses of the lower pillars 400B.

As shown in FIG. 4E, a thin capping layer 406 is formed on a resulting structure. The capping layer 406 has a thickness of approximately 10 Å to approximately 500 Å. The capping layer includes a nitride layer or an oxide layer, or both.

As shown in FIG. 4F, the capping layer 406 and the gate insulation layers 404 which are disposed on the substrate 400 between the pillars P are removed to expose the substrate 400. The capping layer 406 and the gate insulation layers 404 are removed using a wet etch process in the present embodiment, but may be removed using a dry etch process.

As shown in FIG. 4G, a metal layer 407, such as cobalt, nickel or titanium, is deposited on a resulting structure in order to form a silicide layer. At this time, in order for the metal layer 407 to be stably deposited on the exposed substrate 400 between the pillars P, the deposition method used should have an excellent step coverage characteristic. For example, if a PVD (Physical Vapor Deposition) method is used for the deposition of cobalt, an overhang occurs due to a poor step coverage characteristic so that the deposited cobalt may not reach the exposed substrate 400 between the pillars P. Thus, it is desirable to use a CVD (Chemical Vapor Deposition) method or an ALD (Atomic Layer Deposition) method for the cobalt deposition. The deposited metal layer 407 may have a thickness of approximately 30 Å to approximately 500 Å.

As shown in FIG. 4H, a first heat treatment, e.g., an RTP (Rapid Thermal Processing) method, is applied to the resulting structure so that a silicide layer 408 is formed on the exposed substrate 400 between the pillars P. The first heat treatment may be performed at several hundred temperatures.

Then, a portion of the metal layer 407, which has not reacted with the substrate during the first heat treatment, is removed by a wet cleaning process. At this time, the wet cleaning process can be performed using a sulfuric acid (H₂SO₄) solution or a SPM solution in which sulfuric acid (H₂SO₄) and hydrogen peroxide (H₂O₂) are mixed.

Additionally, a second heat treatment is performed to reduce the resistance of the silicide layer 408. The second heat treatment is optionally performed according to application.

Then, in order to prevent the oxidation of the silicide layer 408, a material such as a nitride layer is deposited thinly (e.g., approximately 5 Å to approximately 90 Å) on the surface of the silicide layer 408. Such a process is performed optionally according to application.

As shown in FIG. 4I, an insulation layer 409 is formed on the resulting structure and then the insulation layer 409 is planarized.

Then, a photoresist pattern (not illustrated) is formed on the planarized insulation layer 409 to expose the substrate 400 between rows of the pillars P arranged in the first direction.

The insulation layer 409 is etched using the photoresist pattern as an etching mask so that the silicide layer 408 is exposed. The silicide layer 408 and the substrate 400 under the silicide layer 408 are etched. As a result, an isolation trench T, which extends along a direction parallel to the first direction, is formed in the substrate 400 between the rows of the pillars P arranged in the first direction. The isolation trench T extends below the silicide layer 408 to separate the silicide layer 408 and form bit lines 408A. Each bit line 408A surrounds a pillar P and extends along the first direction.

Therefore, since the bit line is formed using the silicide layer, the resistance and capacitance of the bit line are reduced significantly when compared to the conventional bit line.

Although not illustrated in the drawings, sequentially executed are a process of forming a word line which is electrically connected to the gate electrode 405 and extends along the second direction, a process of removing the hard mask pattern 402 and the pad oxide layer 401 to expose the pillar P, and a process of forming a contact plug and a storage electrode on the exposed pillar P.

Accordingly, the method of fabricating a semiconductor device with a vertical channel transistor according to the present invention can improve the characteristics of the device by using a silicide forming process instead of a conventional impurity doping process at the time of forming a bit line to reduce the resistance and capacitance of the bit line.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A method of fabricating a semiconductor, the method comprising:
forming first and second pillars on a silicon substrate, the first and second pillars being of the same material as the substrate, the first and second pillars defining a space therebetween;
forming a capping layer over the first and second pillars and the space defined therebetween;
removing a portion of the capping layer formed over the space defined between the first and second pillars, wherein a portion of the substrate provided between the first and second pillars is exposed after the capping layer is removed;
forming a metal layer over the capping layer and the exposed portion of the substrate that is provided between the first and second pillars;
applying a first heat treatment to the metal layer, so that a first portion of the metal layer in contact with the exposed portion of the substrate is converted to a silicide layer and a second portion of the metal layer not in contact with the exposed portion of the substrate remains as the metal layer;
removing the second portion of the metal layer, wherein the silicide layer remains at the space defined between the first and second pillars after the second portion of the metal layer is removed; and
forming an isolation trench in the substrate at the space defined between the first and second pillars, the isolation trench extending below the silicide layer and separating the silicide layer into a first silicide structure and a second silicide structure, the first silicide structure being associated with the first pillar and the second silicide structure being associated with the second pillar.

2. The method of claim 1, wherein the capping layer includes a nitride layer or an oxide layer, or both, the capping layer having a thickness of approximately 10 Å to approximately 500 Å.

3. The method of claim 1, wherein the removing-a-portion-of-the-capping-layer step includes a wet etching process to expose the substrate.

4. The method of claim 1, wherein the metal layer has a thickness of approximately 30 Å to approximately 500 Å.

5. The method of claim 1, wherein the first heat treatment includes a rapid thermal processing (RTP) method.

6. The method of claim 1, wherein the second portion of the metal layer is removed by using a sulfuric acid solution or a SPM solution.

7. The method of claim 1, further comprising performing a second heat treatment after forming the silicide layer.

8. The method of claim 1, further comprising forming an oxidation preventing layer over the silicide layer.

9. The method of claim 8, wherein the oxidation preventing layer includes a nitride layer and has a thickness of approximately 5 Å to approximately 90 Å.

10. The method of claim 1, wherein the first silicide structure is a first bit line and the second silicide structure is a second bit line, wherein the first pillar defines a first gate structure and the second pillar defines a second gate structure.

11. The method of claim 1, wherein each of the first and second pillars include an upper portion and a lower portion, wherein the lower portion of the pillar is used to define a gate electrode.

12. The method of claim 11, wherein the lower portion of the pillar is recessed.

13. The method of claim 11, further comprising, forming a word line connected to the first and second pillars.

14. The method of claim 13, further comprising:
removing hard mask patterns formed on the upper portions of the pillars to expose the pillars; and
forming storage electrodes on the upper portions of the pillars.

15. A method of fabricating a semiconductor, the method comprising:
forming first and second pillars on a substrate, the first and second pillars defining a space therebetween, the first and second pillars defining first and second gate electrodes;
forming a capping layer over the first and second pillars and the space defined therebetween;
removing a portion of the capping layer formed over the space defined between the first and second pillars, wherein a portion of the substrate provided between the first and second pillars is exposed after the capping layer is removed;
forming a metal layer over the capping layer and the exposed portion of the substrate that is provided between the first and second pillars;
applying a first heat treatment to the metal layer, so that a first portion of the metal layer in contact with the exposed portion of the substrate is converted to a silicide layer; and
forming an isolation trench in the substrate at the space defined between the first and second pillars, the isolation trench extending below the silicide layer and separating the silicide layer into a first silicide structure and a second silicide structure, the first silicide structure being associated with the first pillar and the second silicide structure being associated with the second pillar.
